(19) United States
(12) Patent Application Publication
(10) Pub. No.: US 2014/0352773 A1
(43) Pub. Date: Dec. 4, 2014

(54) SOLAR CELL

(71) Applicant: NEO SOLAR POWER CORP., Hsinchu City (TW)

(72) Inventors: SHANG-YU CHUANG, HSINCHU CITY (TW); SHIH-DA LIN, HSINCHU CITY (TW); YEH-MING WANG, HSINCHU CITY (TW); WEI-MING CHEN, HSINCHU CITY (TW); YU-WEI TAI, HSINCHU CITY (TW); SHUAI-KAI HUANG, HSINCHU CITY (TW); JUI-LIN WANG, HSINCHU CITY (TW)

(73) Assignee: NEO SOLAR POWER CORP., Hsinchu City (TW)

(21) Appl. No.: 14/169,652

(22) Filed: Jan. 31, 2014

Related U.S. Application Data
(60) Provisional application No. 61/832,154, filed on Jun. 7, 2013.

(30) Foreign Application Priority Data
May 31, 2013 (TW) 102119505

(51) Int. Cl. H01L 31/0224

(52) U.S. Cl. CPC H01L 31/022433
USPC 136/256

(57) ABSTRACT

A solar cell includes a photovoltaic substrate having a first surface and a second surface and a plurality of bus bar electrode net structures. The bus bar electrode net structures are separately disposed on the first surface, each bus bar electrode net structure includes a bus bar electrode, a plurality of finger electrodes, at least one connecting line electrode and at least one vertical finger electrode. The bus bar electrode is disposed on the first surface. The finger electrodes are separately disposed at two sides of the bus bar electrode. The connecting line electrode is disposed on the first surface. Each connecting line electrode connects with ends of at least two finger electrodes. The vertical finger electrode is disposed on the first surface, and is parallel to the bus bar electrode and disposed between the two ends of the finger electrode to connect with at least two adjacent finger electrodes.

### CROSS-REFERENCES TO RELATED APPLICATIONS

This non-provisional application claims priority under 35 U.S.C. §119(a) on Patent Application No. 102119505 filed in Taiwan, R.O.C. on 2013/05/31, the teachings of which is incorporated herein. This application claims priority under 35 U.S.C. §119(e) to provisional application No. 61/832,154 filed on 2013/06/07, which is also incorporated by reference herein.

### BACKGROUND

1. Technical Field

The disclosure relates to a solar cell having better electroluminescence performance than prior solar cells.

2. Related Art

After conventional solar cells are manufactured, quality check procedures must be applied to the final products to ensure the quality of the conventional solar cells. The quality check procedures include material defect, sintering wave, contamination, micro-crack, broken finger, and so forth. Generally, electrical testing methods are applied during manufacturing, to reject conventional solar cells with the defect mentioned previously; however, the micro-crack defect and the broken finger defect can only be detected by close external inspection. Although the micro-crack defects and the broken finger defects do not really influence the conversion efficiency of the conventional solar cell, they do worsen the stability and reduce the life time of the conventional solar cell.

Among numerous external inspection methods, electroluminescence (EL) method is the most popular. In the EL method, a positive current is applied to the solar cell, so that the solar cell emits near infrared light (NIR light) as light emitting diodes, and the light intensity is corresponding to the inputted current and the defect of the solar cell. When defects, such as broken finger defects, micro-crack defects, etc, are presented in the conventional solar cell, no light is emitted from the defect-corresponding region of conventional solar cell.

Please refer to FIG. 1A, which is a perspective view of a conventional solar cell. The conventional solar cell includes a photovoltaic substrate 100, three bus bar electrodes 120 and a plurality of finger electrodes 110. The three bus bar electrodes 120 and the finger electrodes 110 are assembled on the photovoltaic substrate 100. A broken finger portion 111 is formed on the region 1 of the conventional solar cell during manufacturing. Hereafter, once the finger electrode 110 has the broken finger region 111, it is called as broken finger electrode 115.

Additionally, please refer to FIG. 1B, which is an enlarged view of the region 1 of the conventional solar cell. When a positive current is applied to the conventional solar cell, NIR light should be emitted from the conventional solar cell; however, since the broken finger portion 111 has formed on the region 1, the current path is too long and the current cannot reach, therefore, no NIR light will emitted from the broken finger electrode 115. Once an infrared camera is used to take an IR photo of the region 1 of the conventional solar cell, the broken finger electrode 115 is dark colored in the IR photo; that is, no current passes through.

Once the broken finger electrode 115 is dark colored in the IR photo, the broken finger electrode 115 is considered as with lower energy gathering performance and low efficiency, and the whole conventional solar cell will be rejected due to the defect. In fact, the broken finger electrode 115 is still able to gather energy. Therefore, the issue of how to improve the distinguished ability of the real failed finger electrode and the broken finger electrode which can collect energy, reduce the broken finger portion 111 of the solar cell and improve the ability of gathering energy of the solar cell, remains an important topic for developing solar cell technologies.

### SUMMARY

In view of this, the disclosure proposes a solar cell including a substrate and a plurality of bus bar electrode net structures. The photovoltaic substrate has a first surface and a second surface. The bus bar electrode net structures are separately disposed on the first surface of the substrate, each bus bar electrode net structure includes a bus bar electrode, a plurality of finger electrodes, at least one connecting line electrode and at least one vertical finger electrode. The bus bar electrode is disposed on the first surface of the substrate. The finger electrodes are separately disposed at two sides of the bus bar electrode. The at least one connecting line electrode is disposed on the first surface of the substrate, and each connecting line electrode connects with ends of at least two finger electrodes. The at least one vertical finger electrode is disposed on the first surface of the substrate, and each vertical finger electrode is parallel to the bus bar electrode and disposed between the two ends of the finger electrode so as to connect with at least two adjacent finger electrodes.

According to the disclosure, the EL testing inactive problem and the low power generating problem occurred in prior arts can be solved, providing a solar cell with great quality.

The detailed features and advantages of the disclosure are described below in great detail through the following embodiments, the content of the detailed description is sufficient for those skilled in the art to understand the technical content of the disclosure and to implement the disclosure there accordingly. Based upon the content of the specification, the claims, and the drawings, those skilled in the art can easily understand the relevant objectives and advantages of the disclosure.

### BRIEF DESCRIPTION OF THE DRAWINGS

The disclosure will become more fully understood from the detailed description given herein below for illustration only and thus not limitative of the disclosure, wherein:

FIG. 1A is a schematic view of a conventional solar cell;

FIG. 1B is an enlarged view of FIG. 1A;

FIG. 2A is a schematic view of a first embodiment of a solar cell of the disclosure;

FIG. 2B is an enlarged view of FIG. 2A;

FIG. 2C is a schematic view for showing a broken finger portion is formed on the first embodiment of the solar cell;

FIG. 3A is a schematic view of a second embodiment of a solar cell of the disclosure;

FIG. 3B is an enlarged view of FIG. 3A;

FIG. 4A is a schematic view of a third embodiment of a solar cell of the disclosure;

FIG. 4B is an enlarged view of FIG. 4A;

FIG. 5A is a schematic view of a fourth embodiment of a solar cell of the disclosure;

FIG. 5B is an enlarged view of FIG. 5A;

FIG. 6A is a schematic view of a fifth embodiment of a solar cell of the disclosure;

FIG. 6B is an enlarged view of FIG. 6A;

FIG. 7 is an enlarged view for showing vertical finger electrodes are interlaced with bus bar electrodes;

FIG. 8 is an enlarged view for showing that two vertical finger electrodes are disposed between two finger electrodes; and

FIG. 9 is a schematic view of a sixth embodiment of a solar cell of the disclosure.

### DETAILED DESCRIPTION

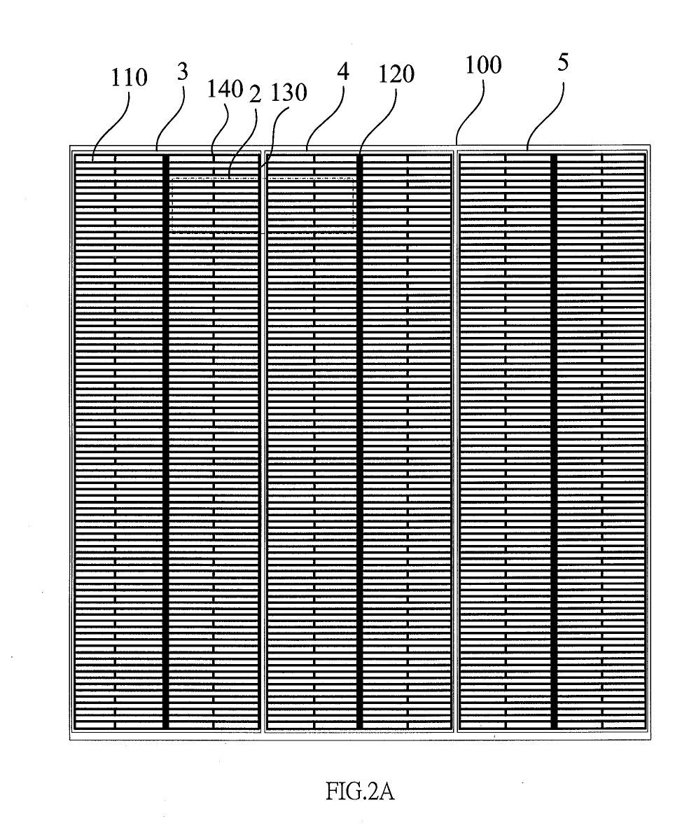

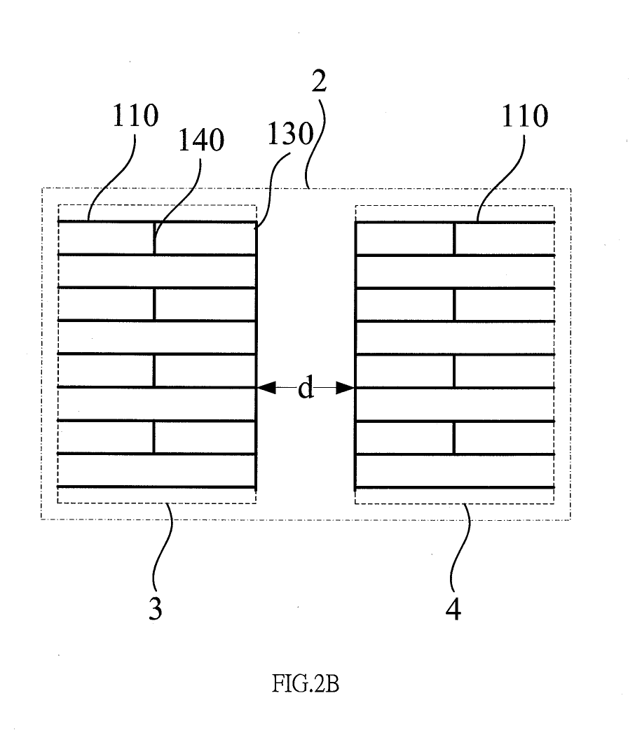

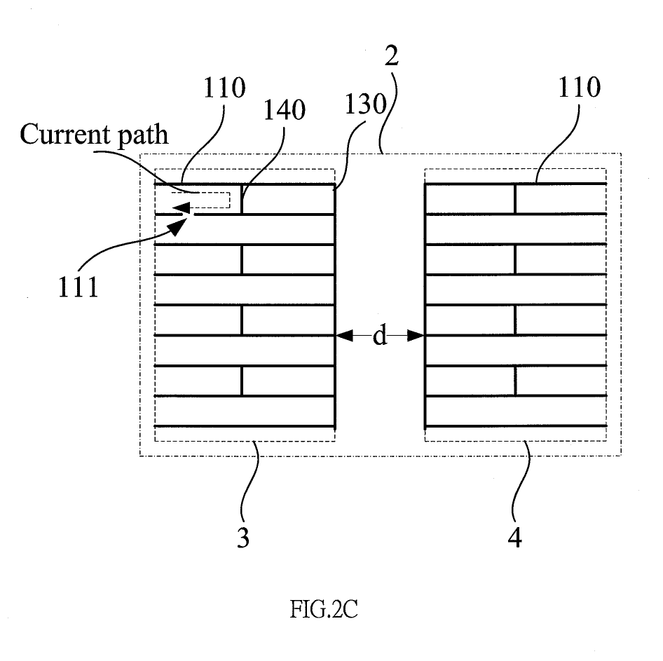

Please refer to FIG. 2A, which is a schematic view of a first embodiment of a solar cell of the disclosure; refer to FIG. 2B, which is an enlarged view of the region 2 of the solar cell shown in FIG. 2A. The solar cell includes a photovoltaic substrate 100, a plurality of bus bar electrodes 120, a plurality of finger electrodes 110, a plurality of connecting line electrodes 130 and a plurality of vertical finger electrodes 140. The photovoltaic substrate 100 has a first surface and a second surface. In this embodiment, the solar cell includes three bus bar electrodes 120. The bus bar electrodes 120 are separately disposed on the photovoltaic substrate 100. Substantially, as shown in FIG. 2A, the solar cell includes three sets of bus bar electrode net structures 3, 4, 5 separately disposed on the photovoltaic substrate 100. Each bus bar electrode net structure 3, 4, 5 includes one bus bar electrode 120, a plurality of finger electrodes 110, a plurality of connecting line electrodes 130 and a plurality of vertical finger electrodes 140. The bus bar electrode 120 is disposed at the first surface of the photovoltaic substrate 100. The finger electrodes 110 are separately disposed at two sides of the bus bar electrode 120. The connecting line electrodes 130 are disposed at the first surface of the photovoltaic substrate 100, and each connecting line electrode 130 connects with the ends of at least two adjacent finger electrodes 110. The vertical finger electrodes 140 are disposed on the first surface of the photovoltaic substrate 100, and each vertical finger electrode 140 is parallel to the bus bar electrode 120 and is disposed between the two ends of the finger electrode 110 so as to connect with at least two adjacent finger electrodes 110. As shown in FIG. 2A, one end of the finger electrode 110 is connected to the bus bar electrode 120 and the other end of the finger electrode 110 is connected to the connecting line electrode 130, and the vertical finger electrode 140 is disposed between two ends of the finger electrode 110, so the vertical finger electrode 140 is disposed between the bus bar electrode 120 and the connecting line electrode 130.

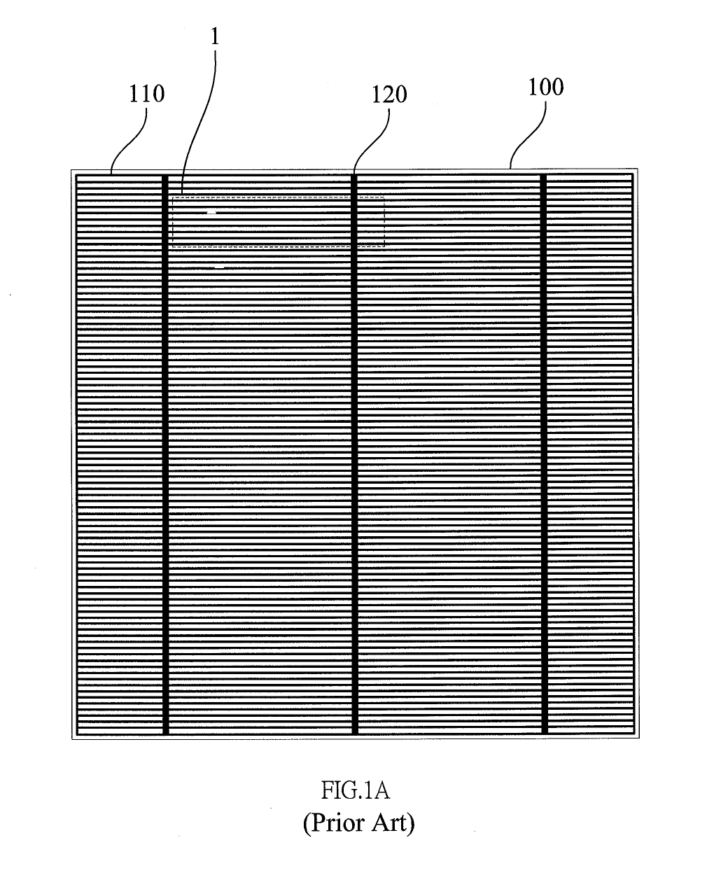

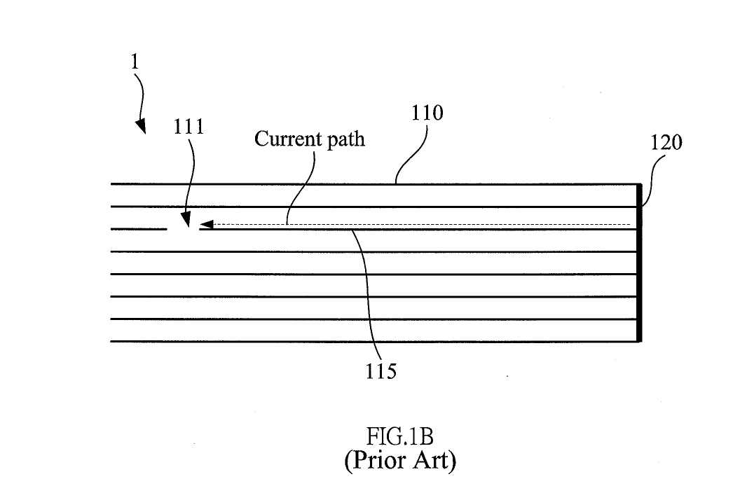

As compared with the prior art shown in FIGS. 1A and 1B, the bus bar electrode net structures 3, 4, 5 disclosure shown in FIGS. 2A and 2B are disposed on the photovoltaic substrate 100 separately. Furthermore, the bus bar electrode net structures 3, 4, 5 of present invention include the vertical finger electrodes 140 and the connecting line electrodes 130, and each vertical finger electrode 140 connects with at least two adjacent finger electrodes 110. As shown in FIG. 2B, due to the vertical finger electrodes 140 and the connecting line electrodes 130, the current path upon EL testing is shortened as compared to the prior art. In this embodiment, a second angle defined between the vertical finger electrode 140 and the bus bar electrode 120 is 0 degree, that means second angle is defined by the orientation of the vertical finger electrode 140 and the orientation of the bus bar electrode 120; namely, the vertical finger electrodes 140 are parallel to the bus bar electrodes 120, but embodiments of the disclosure are not limited thereto. In some embodiments, the second angle defined between the vertical finger electrode 140 and the bus bar electrode 120 is smaller than 45 degrees, for example, 20 degrees; in other words, the vertical finger electrode 140 is leanly connected with its two adjacent finger electrodes 110.

Additionally, please refer to the broken line portion 111 shown in FIG. 2C. Since the vertical finger electrodes 140 and the connecting line electrodes 130 are both connected with the finger electrode 110, the current generated from the solar cell has more valid paths to pass through and the current paths are shortened. When the broken finger portion 111 is formed on the finger electrode 110, the current can still pass to the broken finger region 111 through the vertical finger electrodes 140 and the connecting line electrodes 130, so that the broken finger region 111 of the finger electrode 110 can emit NIR light. Therefore, the broken finger region 111 of the finger electrode 110 will not cause the whole finger electrode 110 to be dark colored in the IR photo after connecting with the vertical finger electrodes 140 and the connecting line electrodes 130. That is to say, even if the finger electrode 110 has broken finger portions 111, the current generated near to the broken finger portions 111 can still pass through the bus bar electrode 120 of each bus bar electrode net structure 3, 4, 5 through the vertical finger electrodes 140 and the connecting line electrodes 130. Consequently, the energy generating efficiency of the solar cell is enhanced. Each bus bar electrode net structure 3, 4, 5 can gather the current to the corresponding bus bar electrode 120 through the finger electrodes 110 of the bus bar electrode net structure 3, 4, 5, in which the current is generated from the region covered by the bus bar electrode net structure 3, 4, 5. Since the bus bar electrode net structures 3, 4, 5 are disposed on the photovoltaic substrate 100 separately, the current generated within the region covered by one bus bar electrode net structure 3, 4, 5 will not pass through another region covered by another bus bar electrode net structure 3, 4, 5. Additionally, the bus bar electrodes 120 of the bus bar electrode net structures 3, 4, 5 are substantially parallel with each other, and the center of each bus bar electrode 120 is located at the center of each corresponding bus bar electrode net structure 3, 4, 5.

An interval width d is defined between each two adjacent bus bar electrode net structures 3, 4, 5, as the two bus bar electrode net structures 3, 4 shown in FIG. 2B. The interval width d is defined between 30 micrometers to 5000 micrometers. Within the interval width, the energy generating efficiency of the solar cell is not reduced significantly.

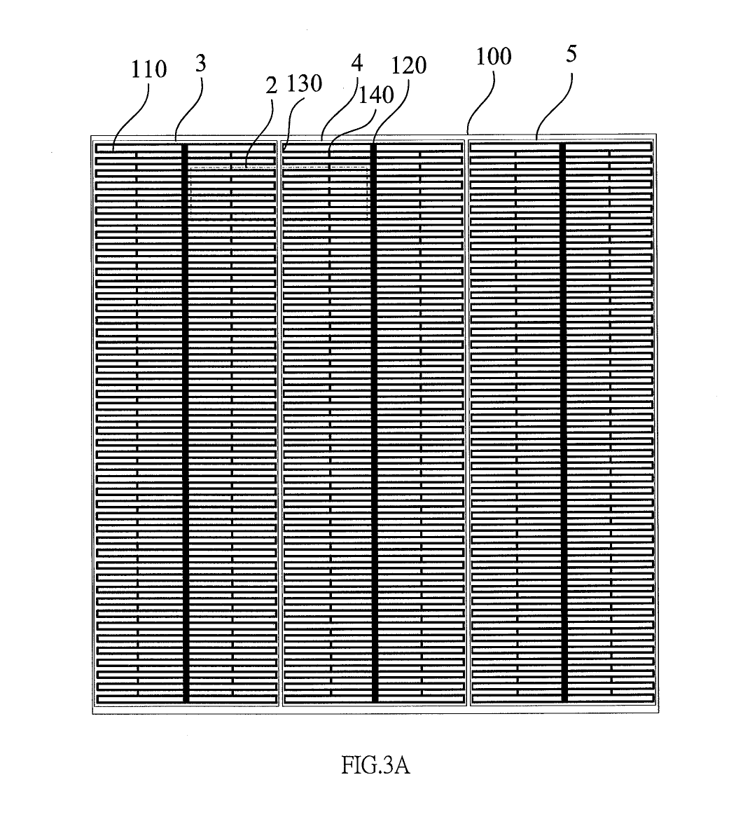

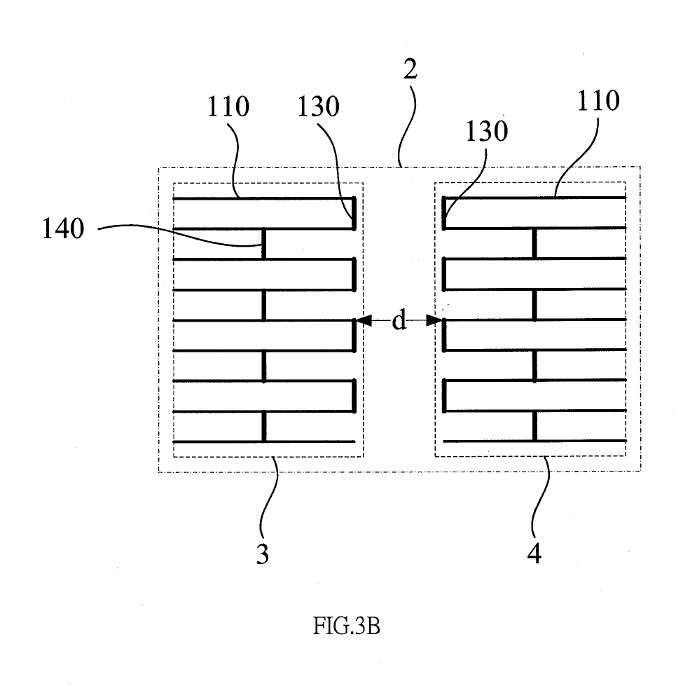

Please refer to FIG. 3A, which is a schematic view of a second embodiment of the solar cell of the disclosure; additionally, please refer to FIG. 3B, which is an enlarged view of the region 2 of the solar cell shown in FIG. 3A. In this embodiment, each connecting line electrode 130 connects with the ends of the adjacent two finger electrodes 110, so that the two finger electrodes 110 are connected with each other. As shown in FIG. 3A, two ends of the finger electrode 110 are respectively connected to the bus bar electrode 120 and the connecting line electrode 130, and the vertical finger electrode 140 is disposed between the two ends of the finger electrode 110, so the vertical finger electrode 140 is disposed between the bus bar electrode 120 and the connecting line electrode 130. However, in this embodiment, each vertical finger electrode 140 and each corresponding connecting line electrode 130 are connected with different adjacent finger electrodes 110. Namely, the finger electrode 110 connected with one vertical finger electrode 140 does not connect with the connecting line electrode 130 corresponding to the vertical finger electrode 140. As shown in FIGS. 3A-3B, the width of each connecting line electrode 130 is defined between 10 micrometers to 200 micrometers, and the interval width d defined between each two adjacent connecting line electrodes (or each two adjacent bus bar electrode net structures 3, 4, 5) is defined between 30 micrometers to 5000 micrometers. The width of each vertical finger electrode 140 is defined between 10 micrometers to 200 micrometers. Additionally, as shown in FIGS. 3A-3B, after connecting with the adjacent finger electrodes 110, a line shape is presented by the connecting line electrodes 130; that is to say, the connecting line electrodes 130 are disposed along the bus bar electrode 120. In other embodiments, wave-like or zigzag structures are presented by the connecting line electrodes 130, but embodiments of the disclosure are not limited thereto. For any two adjacent connecting line electrodes 130, the interval width d defined therebetween is not fixed and can be changed within the interval width d as mentioned above. A first angle defined between the connecting line electrode 130 and the bus bar electrode 120 is from 0 degree to 80 degrees.

The embodiments shown in FIGS. 2A-2B and FIGS. 3A-3B, the adjacent portion between two adjacent bus bar electrode net structures 3, 4 is parallel to the bus bar electrode 120, but embodiments of the disclosure are not limited thereto.

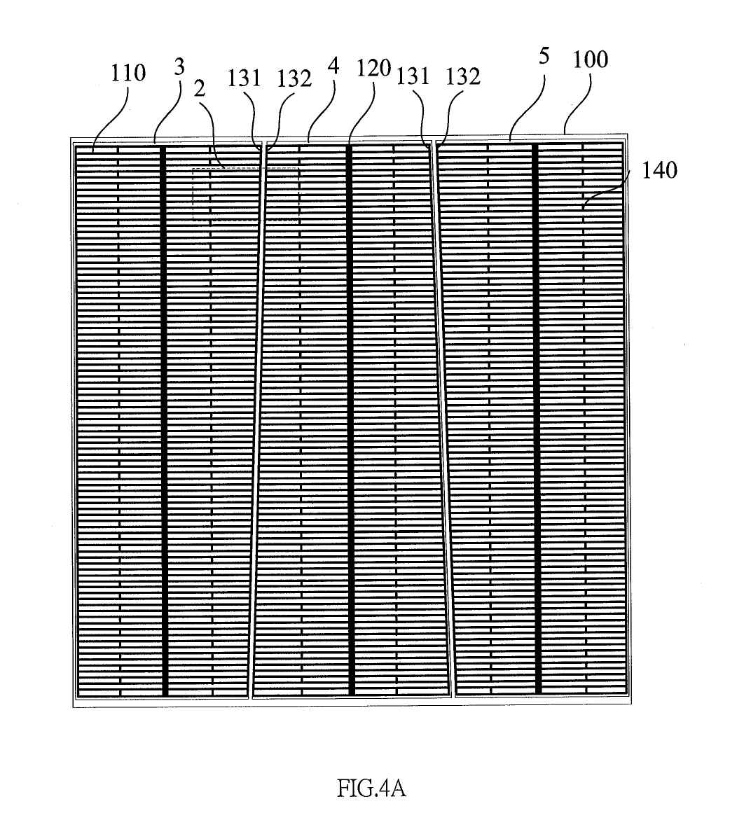

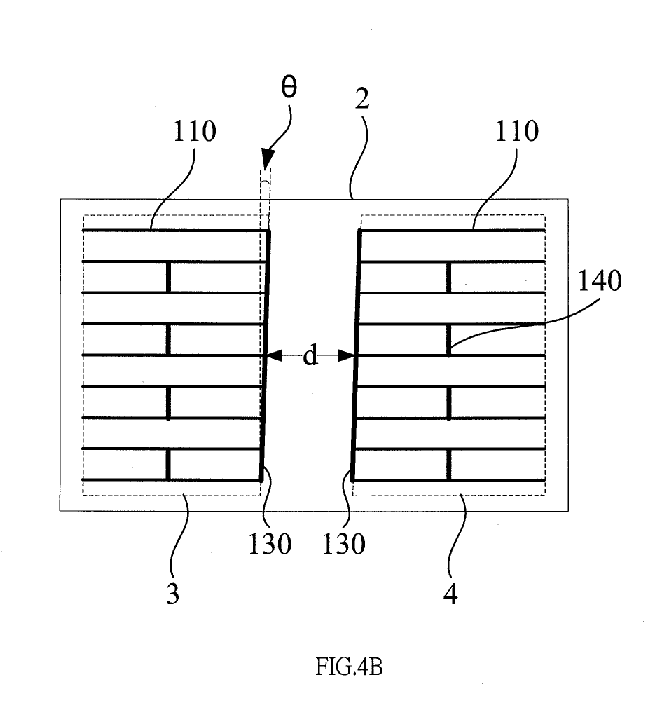

Please refer to FIG. 4A, which is a schematic view of a third embodiment of the solar cell of the disclosure; additionally, please refer to FIG. 4B, which is an enlarged view of the region 2 of the solar cell shown in FIG. 4A. In this embodiment, a third angle is defined between the adjacent portion between two adjacent bus bar electrode net structures 3, 4 and the bus bar electrode 120, for example, the third angle θ is 10 degrees.

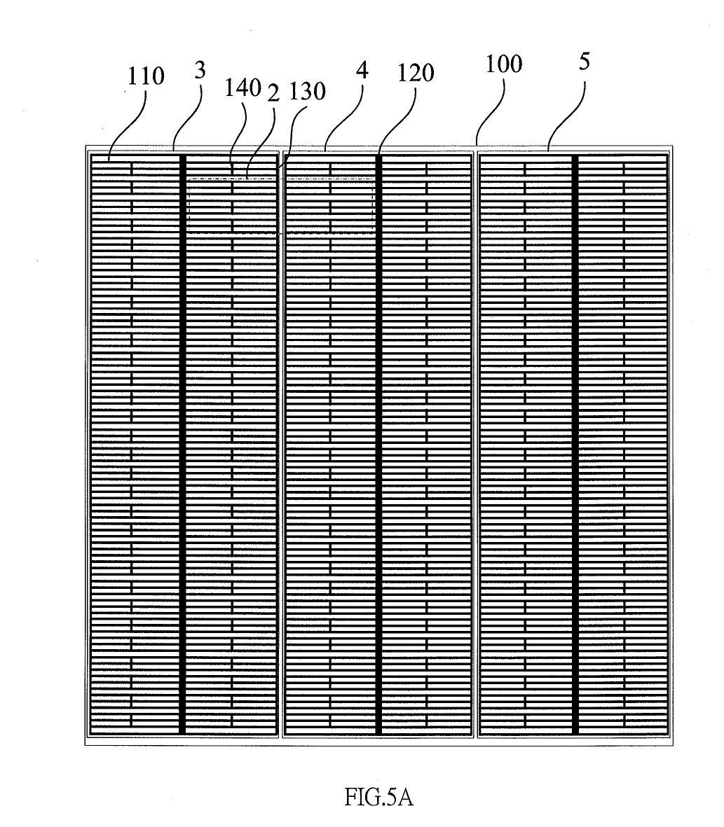

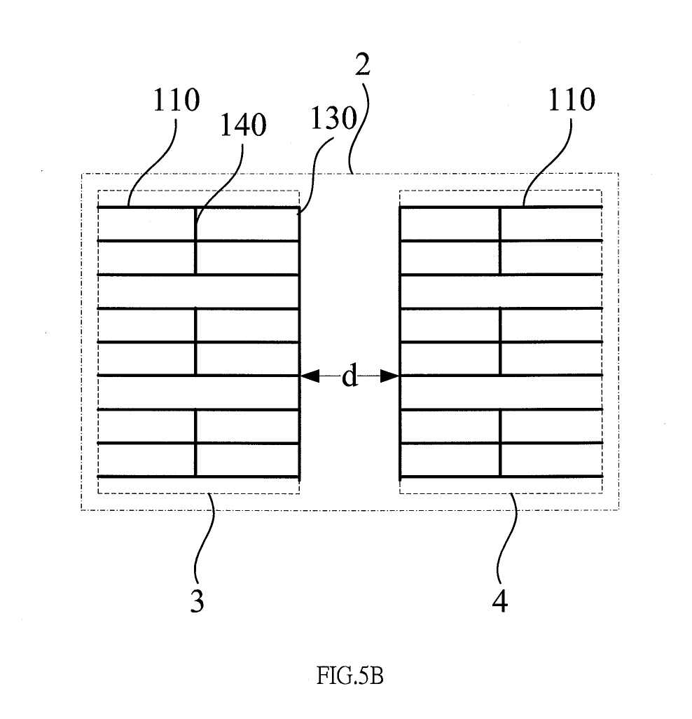

Please refer to FIG. 5A, which is a schematic view of a fourth embodiment of the solar cell of the disclosure; additionally, please refer to FIG. 5B, which is an enlarged view of the region 2 of the solar cell shown in FIG. 5A. In this embodiment, each vertical finger electrode 140 is disposed at two sides of the bus bar electrode net structure 3, 4, 5, and each vertical finger electrode 140 connects with three finger electrodes 110, so that the three finger electrodes 110 are partially connected by the vertical finger electrode 140.

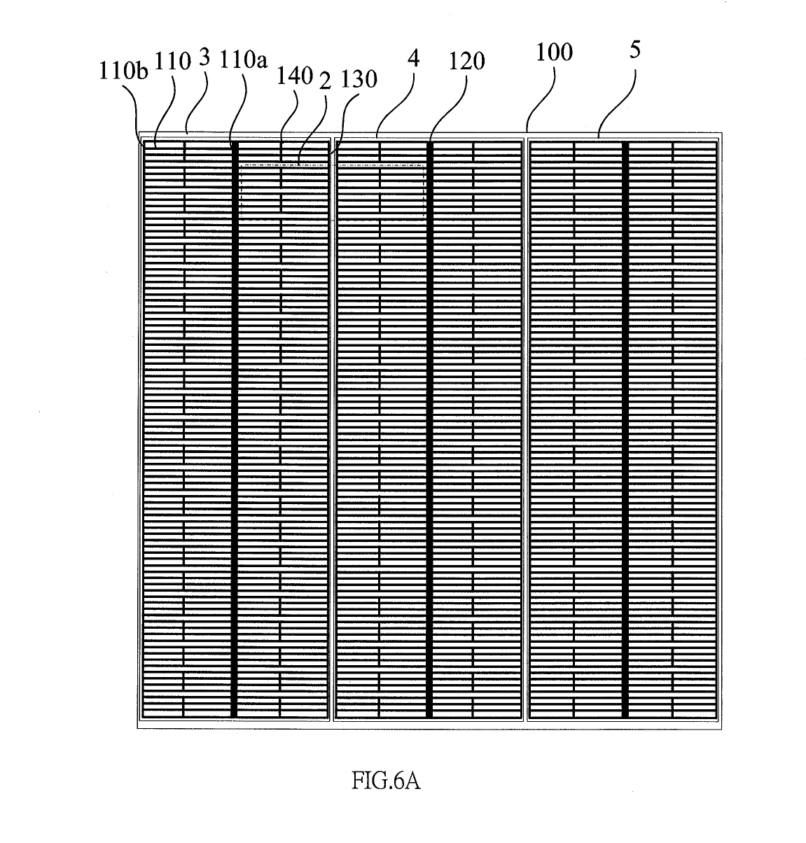

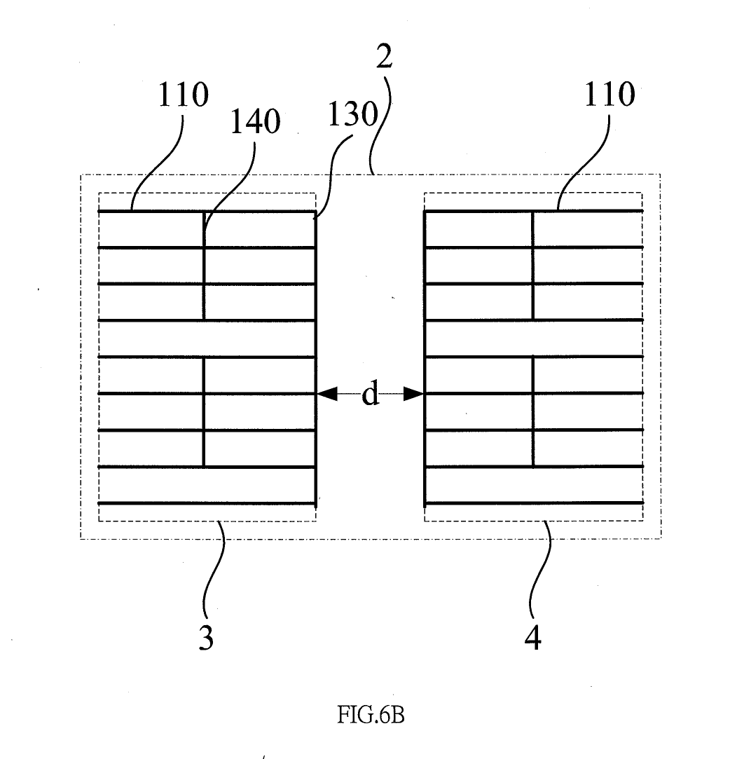

Please refer to FIG. 6A, which is a schematic view of a fifth embodiment of the solar cell of the disclosure; additionally, please refer to FIG. 6B, which is an enlarged view of the region 2 of the solar cell shown in FIG. 6A. In this embodiment, each vertical finger electrode 140 is disposed at the two sides of the bus bar electrode net structure 3, 4, 5, and each vertical finger electrode 140 connects with four finger electrodes 110, so that the four finger electrodes 110 are partially connected by the vertical finger electrode 140.

According to the description mentioned above, the disposing of the connecting line electrodes 130 can be classified as, but not limited to, the following.

Firstly, the connecting line electrodes 130 are disposed at the two sides of each bus bar electrode net structure 3, 4, 5 as shown in FIG. 2A. And, the connecting line electrodes 130 are connected with the end portions of the finger electrodes 110 so as to connect all the finger electrodes 1110 with each other.

Secondly, the connecting line electrodes 110 are disposed at the two sides of each bus bar electrode net structure 3, 4, 5 as shown in FIG. 3A. Additionally, each connecting line electrode 130 connects with open ends of two finger electrodes 110, in which the open end of the finger electrode 110 is near to the interval width d. In other words, the connecting line electrodes 130 are connected with the end portions of the finger electrodes 110 so as to connect parts of the finger electrodes 110 with each other. Based on this, since only parts of the adjacent finger electrodes 110 are connected with each other by the connecting line electrodes 130, not only the shielded regions of the solar cell can be reduced further, but also the EL testing inactive problem and the low power generating problem can be solved.

Furthermore, according to the description mentioned above, the vertical finger electrodes 140 can be disposed in the two sides of the bus bar electrode net structure 3, 4, 5, as shown in FIG. 2A, FIG. 3A, FIG. 5A and FIG. 6A. Additionally, the vertical finger electrodes 140 are capable of connecting with two finger electrodes 110, three finger electrodes 110 or four finger electrodes 110, so that the finger electrodes 110 are partially connected with each other, but embodiments of the disclosure are not limited thereto; in some embodiments, the vertical finger electrodes 140 are capable of connecting with a number of finger electrodes 110 in which the number of the finger electrodes 110 is greater than four.

Furthermore, the vertical finger electrodes 140 are disposed between the connecting line electrodes 130 and the bus bar electrodes 120, for instance, the vertical finger electrode 140 can be disposed near to the bus bar electrode 120, and a first distance defined between the vertical finger electrode 140 and the bus bar electrode 120 is smaller than one-fourth of a second distance defined between the bus bar electrode 120 and the connecting line electrode 130, so that the issue that broken finger portions 111 are easily formed on the finger electrodes 110 near to the bus bar electrodes 120 upon printing the electrodes can be solved, but embodiments of the disclosure are not limited thereto; those skilled in this art can alternate the disposing position of the vertical finger electrodes 140 according to the pattern of the printed electrodes and the electrode materials, so as to resolve the EL testing inactive problem and the low power generating problem.

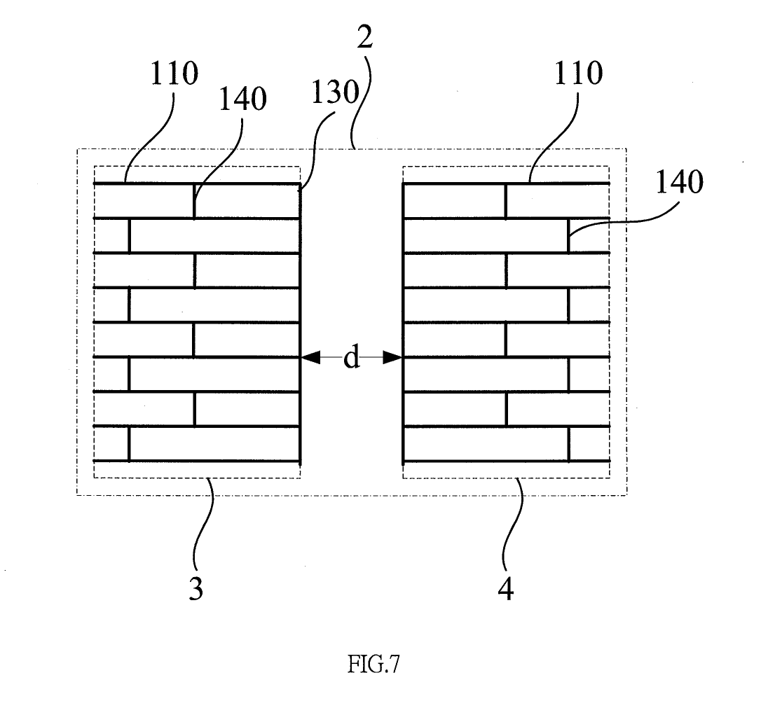

In other embodiments, within the same bus bar electrode net structure 3, 4, 5, the distances defined between each vertical finger electrode 140 and the connecting line electrode 130 can be the same or different; namely, the vertical finger electrodes 140 can be aligned along one line having the same orientation with the bus bar electrode 120, hereafter called as linear arranged, as shown in FIGS. 2A-6B; or, the vertical finger electrodes 140 can be aligned along two lines in which the two lines are parallel with each other and have the same orientation with the bus bar electrode 120, here after called as interlaced arranged, as shown in FIG. 7.

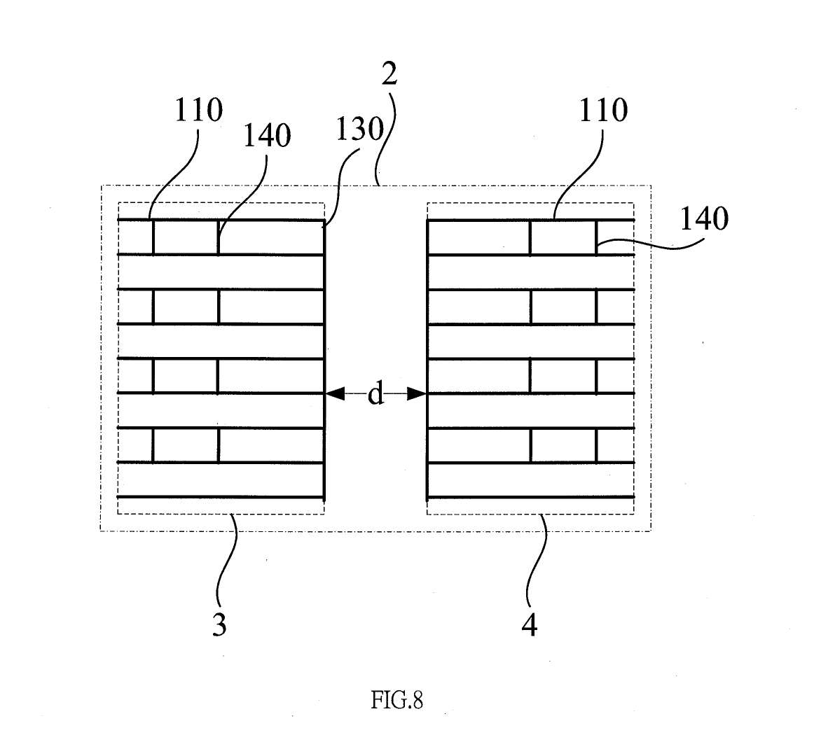

In the embodiments mentioned above, only one vertical finger electrode 140 is disposed between the bus bar electrode 120 and the connecting line electrodes 130; in other embodiments, another vertical finger 140 is additionally disposed between the vertical finger electrode 140 and the bus bar electrode 120 or between the vertical finger electrode 140 and the connecting line electrode 130; in other words, one finger electrode 110 connects with two or more than two vertical finger electrodes 140. For example, as shown in FIG. 8, two vertical finger electrodes 140 are separately disposed between two finger electrodes 110, and the vertical finger electrodes 140 can be disposed along the orientation of the bus bar electrode 120 in linear arranged or in interlaced arranged, so that plenty of current paths are formed on the solar cell. Consequently, as mentioned previously, the EL testing inactive problem and the low power generating problem can also be resolved.

In other embodiments, a spacing width defined between the two adjacent finger electrodes 110 can be the same or different; for example, the spacing width near to the bus bar electrode 120 can be larger than the spacing width near to the connecting line electrode 130; or, the spacing width near to the bus bar electrode 120 can be smaller than the spacing width near to the connecting line electrode 130. Please refer to FIG. 6A, the finger electrode 110 has a first end 110a and a second end 110b opposite to the first end 110a, the first end 110a of the finger electrode 110 connects to the bus bar electrode 120, the difference between one spacing width of the first end 110a and another spacing width of the second end 110b is defined from 0 micrometers to 100 micrometers. When the spacing width near to the bus bar electrode 120 is not equal to the spacing width near to the connecting line electrode 130, the pattern of the finger electrodes 110 are formed a structure like triangle, trapezoid, or a combination of multi-squares with different lengths, or can be formed by any two lines of curve lines, straight lines or inclined lines. Preferably, the finger electrodes 110 forms a structure like a combination of multi-squares with different lengths, and the spacing width near to the bus bar electrode 120 is larger than the spacing width near to the connecting line electrode 130.

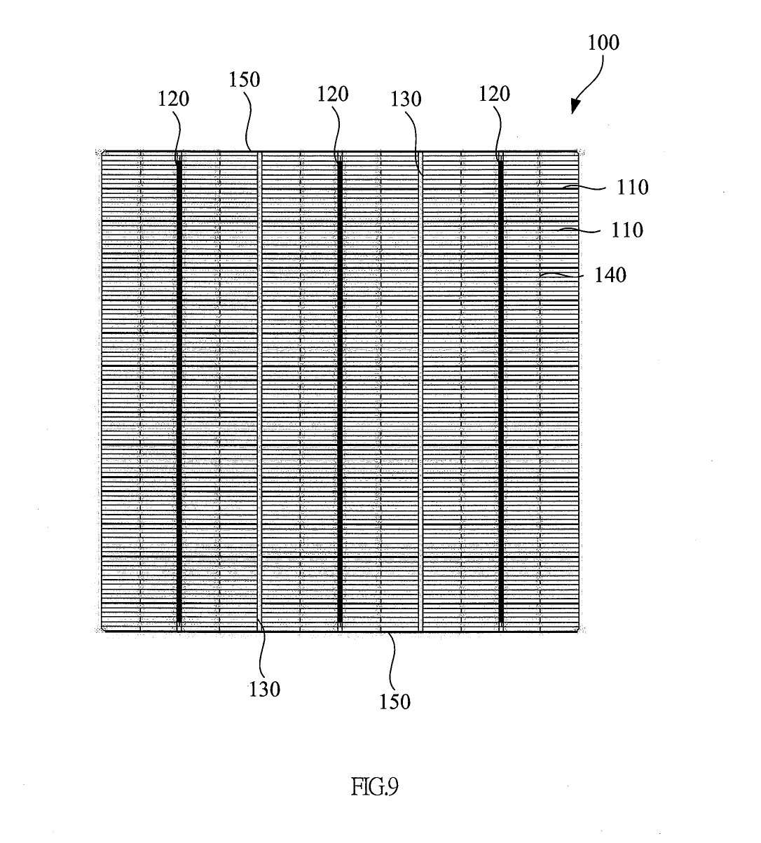

Please refer to FIG. 9, which is a schematic view of a sixth embodiment of a solar cell of the disclosure. In this embodiment, the front surface of photovoltaic substrate 100 includes a front electrode structure including three bus bars 120, a plurality of finger electrodes 110, a plurality of connecting line electrode 130, a plurality of vertical finger electrode 140 and two wide finger electrodes 150. The wide finger electrode 150 connects three bus bar electrodes 120 of adjacent bus bar electrode net structures, and the average width of the wide finger electrode 150 is greater than 100 um. The wide finger electrodes 150 of present invention can prevent finger broken and increase carrier collection.

In other embodiments, two surfaces of a semiconductor substrate of a solar cell are both light incident surface and the said front electrode structure is allocated on each light incident surface.

While the disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A solar cell, comprising:
a photovoltaic substrate, having a first surface and a second surface;
a plurality of bus bar electrode net structures, separately disposed on the first surface of the substrate, each bus bar electrode net structure comprising:
a bus bar electrode, disposed on the first surface of the substrate;
a plurality of finger electrodes, separately disposed at two sides of the bus bar electrode;
at least one connecting line electrode, disposed on the first surface of the substrate, each connecting line electrode connects with the ends of at least two finger electrodes; and
at least one vertical finger electrode, disposed on the first surface of the substrate, each vertical finger electrode is disposed between the two ends of the finger electrode so as to connect with at least two adjacent finger electrodes.

2. The solar cell according to claim 1, wherein an interval width is defined between each two adjacent bus bar electrode net structures, the interval width is defined between 30 micrometers to 5000 micrometers.

3. The solar cell according to claim 1, wherein the bus bar electrodes of the bus bar electrode net structures are substantially parallel with each other.

4. The solar cell according to claim 1, wherein a first angle is defined between the connecting line electrode and the bus bar electrode, the first angle is defined from 0 degree to 80 degrees.

5. The solar cell according to claim 1, wherein the center of each bus bar electrode is located at the center of each corresponding bus bar electrode net structure.

6. The solar cell according to claim 1, wherein the width of each connecting line electrode is defined between 10 micrometers to 200 micrometers.

7. The solar cell according to claim 1, wherein each bus bar electrode net structure comprises a plurality of connecting line electrodes, which connect with the end of the finger electrodes so as to connect all the finger electrodes with each other.

8. The solar cell according to claim 1, wherein each bus bar electrode net structure comprises a plurality of connecting line electrodes, which connect with the end portions of the finger electrodes so as to connect parts of the finger electrodes with each other.

9. The solar cell according to claim 1, wherein each bus bar electrode net structure comprises a plurality of vertical finger electrodes, which are disposed in the two sides of the bus bar electrode net structure, and the vertical finger electrodes are capable of connecting with at least two finger electrodes, so that the two finger electrodes are partially connected with each other.

10. The solar cell according to claim 7, wherein each bus bar electrode net structure comprises a plurality of vertical finger electrodes, which are disposed in the two sides of the bus bar electrode net structure, and the vertical finger electrodes are capable of connecting with at least two finger electrodes, so that the two finger electrodes are partially connected with each other.

11. The solar cell according to claim 8, wherein each bus bar electrode net structure comprises a plurality of vertical finger electrodes, which are disposed in the two sides of the bus bar electrode net structure, and the vertical finger electrodes are capable of connecting with at least two finger electrodes, so that the two finger electrodes are partially connected with each other.

12. The solar cell according to claim 1, wherein the width of each vertical finger electrode is defined between 10 micrometers to 200 micrometers.

13. The solar cell according to claim 1, wherein the finger electrode has a first end and a second end opposite to the first end, the first end of the finger electrode connects to the bus bar electrode, the difference between one spacing width of the first end and another spacing width of the second end is defined from 0 micrometers to 100 micrometers.

14. The solar cell according to claim 13, wherein the finger electrode has a first end and a second end opposite to the first end, the first end of the finger electrode connects to the bus bar electrode, the difference between one spacing width of the first end and another spacing width of the second end is defined from 20 micrometers to 60 micrometers.

15. The solar cell according to claim 1, wherein a second angle is defined between the vertical finger electrode and the bus bar electrode, the second angle is defined from 0 degree to 45 degrees.

16. The solar cell according to claim 15 wherein a second angle is defined between the vertical finger electrode and the bus bar electrode, the second angle is defined from 0 degree to 20 degrees.

17. The solar cell according to claim 1, wherein the solar cell comprises at least one wide finger electrode which is greater than 100 micrometers and connects the bus bar electrode of adjacent bus bar electrode net structures.
